(19) United States
(12) Patent Application Publication
(10) Pub. No.: US 2009/0046502 A1
(43) Pub. Date: Feb. 19, 2009

(54) Metal Magnetic Memory Cell

(75) Inventors: Tom Allen Agan, Saint Paul, MN (US); James Chyi Lai, Saint Paul, MN (US)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: NORTHERN LIGHTS SEMICONDUCTOR CORP., Saint Paul, MN (US)

(21) Appl. No.: 11/839,710

(22) Filed: Aug. 16, 2007

(51) Int. Cl. G11C 11/15; G11C 11/06; H01L 29/82

(52) U.S. Cl. 365/173; 257/422; 365/225.5; 257/E29.323

(57) ABSTRACT

A magnetic memory cell is provided. The memory cell includes a metal device, a first word line, and a second word line. The metal device includes a first magnetic layer having a first dipole; a second magnetic layer having a second dipole; and an conductive layer located between the first and second magnetic layers. The first word line is positioned near the first magnetic layer to change the direction of the first dipole. The second word line is positioned near the second magnetic layer to change the direction of the second dipole. A method of reading/writing a bit in the magnetic memory cell is also provided.

### BACKGROUND

1. Field of Invention

The present invention relates to a metal magnetic memory cell. More particularly, the present invention relates to a dual word line metal magnetic memory cell capable of storing a single bit.

2. Description of Related Art

Magnetoresistive Random Access Memory (MRAM) is a non-volatile computer memory (NVRAM) technology, which has been under development since the 1990s. Continued increases in density of existing memory technologies, notably Flash RAM and DRAM kept MRAM in a niche role in the market, but its proponents believe that the advantages are so overwhelming that MRAM will eventually become dominant.

Unlike conventional RAM chip technologies, in MRAM data is not stored as electric charge or current flows, but by magnetic storage elements. The elements are formed from two ferromagnetic plates, each of which can hold a magnetic field, separated by a thin insulating layer. One of the two plates is a permanent magnet set to a particular polarity, the other's field will change to match that of an external field. A memory device is built from a grid of such “cells”.

The main determinant of a memory system's cost is the density of the components used to make it up. Smaller components, and less of them, means that more “cells” can be packed onto a single chip, which in turn means more can be produced at once from a single silicon wafer. This improves yield, which is directly related to cost.

In order to make memories able to hold more data with a given physical size, memory manufactures typically try to create those memories with as few components as possible. However, the current MRAM requires multiple cells to store a single bit of data, thus making it difficult to reduce the overall device size.

For the forgoing reasons, there is a need for a new magnetic memory cell, so that the density of the memory device may be increased, which reduces the cost of manufacturing.

### SUMMARY

The present invention is directed to a magnetic memory cell, that it satisfies this need of increasing the density of the memory device. The magnetic memory cell comprises a metal device, a first word line, and a second word line. The metal device includes a first magnetic layer having a first dipole; a second magnetic layer having a second dipole; and a conductive layer located between the first and second magnetic layers. The first word line is positioned near the first magnetic layer to change the direction of the first dipole. The second word line is positioned near the second magnetic layer to change the direction of the second dipole. A method of reading/writing a bit in the magnetic memory cell is also provided.

The embodiment of the present invention is capable of storing a single bit of data in a single memory cell, thus creating a very dense non-volatile memory device using only a single cell for each bit of memory. By doing so, less components will be needed per area to obtain a certain size of memory. Not only does fewer components mean more memory per area, but also lower cost and often better performance. Furthermore, the embodiments of the present invention may also be used in a low power and high speed design.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross section view of the magnetic memory cell according to a first preferred embodiment of this present invention;

FIG. 2 is a cross section view of the magnetic memory cell when a logic 1 bit is being written thereto according to a second preferred embodiment of this invention; and

FIG. 3. is a flow diagram of the steps to read the bit in the magnetic memory cell according to the second preferred embodiment of the this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

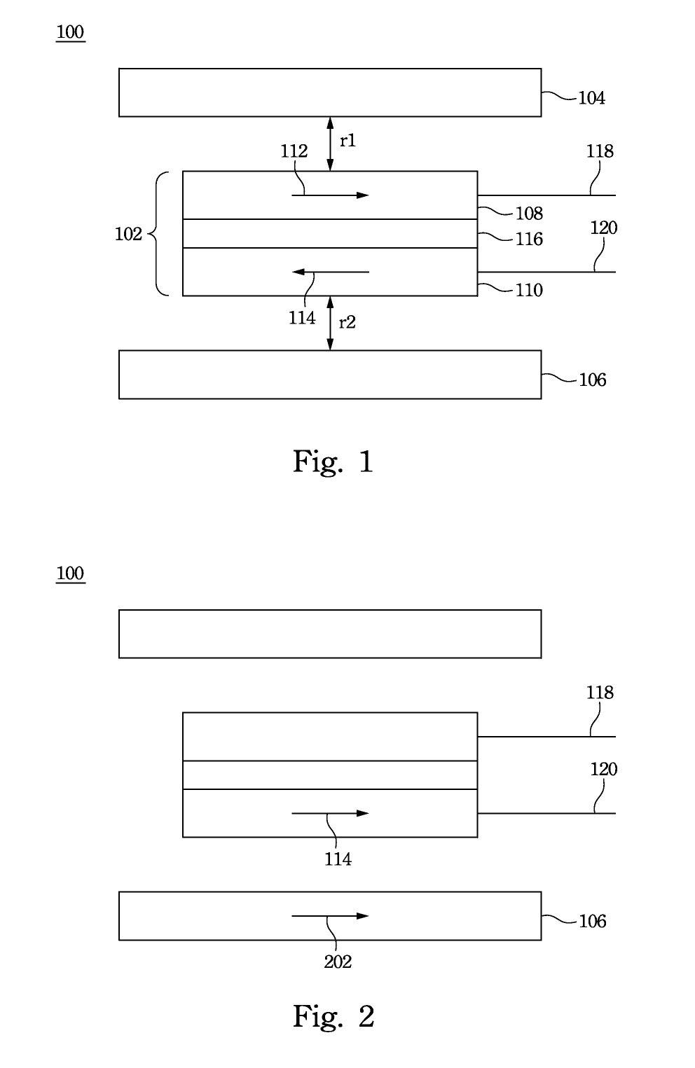

Please refer to FIG. 1, a cross section view of the magnetic memory cell according to a first embodiment of the present invention. The magnetic memory cell 100 includes a metal device 102, a first word line 104, and a second word line 106. The metal device 102 includes a first magnetic layer 108 and a second magnetic layer 110. The two magnetic layers 108, 110 have a first dipole 112 and a second dipole 114, respectively. The magnetic layers 108, 110 may be formed in the same thin film. The direction of the dipoles 112, 114 may be pointing to the right or to the left. Also, the first and second dipoles 112, 114 may change directions according to current induced external magnetic fields. Furthermore, a conductive layer 116 is located between the first and second magnetic layers 108, 110. The conductive layer 116 serves as a barrier between the two magnetic layers 108, 110, and are commonly known as a tunnel barrier.

The first word line 104 is positioned near the first magnetic layer 108 to control and may change the direction of the first dipole 112. The first word line 104 provides the external current needed to induce a magnetic field, which according to the direction of the magnetic field, the direction of the first dipole 112 changes. Therefore, as the direction of the current in the first word line 104 changes, the first dipole 112 changes accordingly. The magnitude of the magnetic field experienced by the first magnetic layer 108 is determined by the magnitude of the current loaded on the first word line 104 and the spacing between the first word line 104 and the first magnetic layer 108. Therefore, as the first word line 104 is located close to the first magnetic layer 108, a first space “r1” is provided so that by shortening the first space r1, the current needed on the first word line 104 may be minimized. Thus, reducing the current on the first word line 104 reduces the power consumption of the memory device. Similarly, the second word line 106 is positioned near the second magnetic layer 110 to change the direction of the second dipole 114. The second space “r2” may be shortened to minimize the current flowing in the second word line 106.

The magnetic memory cell mentioned above is capable of storing a single bit of data therein. Therefore, it is another aspect of the present invention to provide a method for reading/writing a bit in the magnetic memory cell mentioned above. As a second embodiment of the present invention, please refer to FIG. 2. In FIG. 2, an exemplary diagram illustrating the writing of a logic high bit. The logic high bit to be written is generated by a decoder (not shown), which then a control logic circuit controls the direction of the current 202 flowing in the second word line 106 according to the logic high bit. The direction of the current 202 then induces a magnetic field, which points the second dipole 114 to a first direction, which corresponds to the logic high bit. For example, to write the logic high bit, the direction of the current 202 will be controlled to flow in the right direction, which then will point the second dipole 114 to the right. In the same fashion, to write a logic low bit, the direction of the current 202 will be controlled to flow in the left direction, which then will point the second dipole 114 to the left.

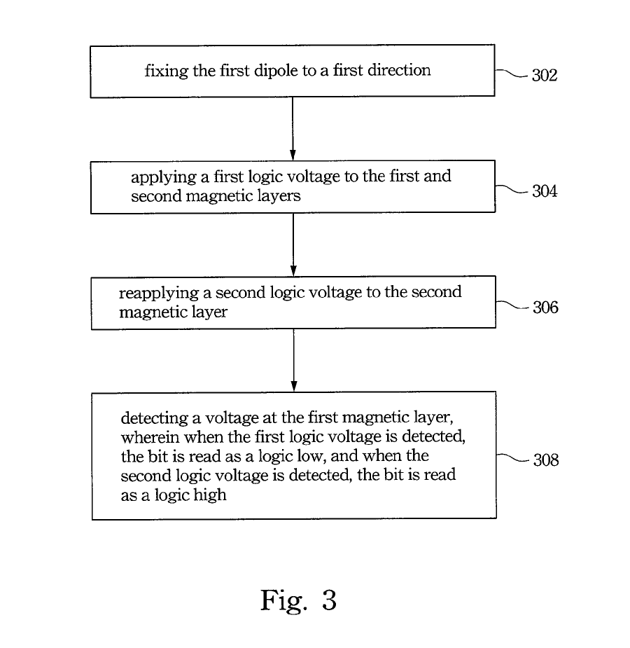

Reading the bit from the magnetic memory cell 100 may be performed by the steps listed in the flow diagram in FIG. 3. In a first step 302, the first dipole 112 of the first magnetic layer 108 is fixed to a first direction. The first direction of the first dipole 112 may be determined by the current loaded on the first word line 104. The first direction may be either left or right. In the second step 304, a first logic voltage is applied to the first and second magnetic layers 108, 110. The first logic voltage may be applied through a bit line and a line select power line electrically connected to the first magnetic layer 108 and the second magnetic layer 110, respectively. The first logic voltage may be a logic low voltage. In other embodiments of the present invention, the second step 304 may be any step serving to reset the first and second magnetic layers 108, 110 to a reference voltage. Next, in step 306, a logic high voltage may be reapplied to the second magnetic layer 110 via the line select power line. After step 306, the bit in the magnetic memory cell 100 may be ready for reading.

For example, in the last step 308, if a dipole pointing to the right is defined as a logic high bit, then when the second dipole 114 is pointing to the right and the first dipole 112 is pointing to the right in step 304, the dipoles are in parallel. When the first and second dipoles 112, 114 are in parallel, the magnetic memory cell 100 becomes conductive, which means the line select power line is electrically connect to the bit line, thus the second logic voltage applied to the line select power line is then detected at the bit line. On the other hand, when the second dipole 114 is pointing to the left, meaning a logic low bit is stored in the memory cell 100, the first and second dipoles 112, 114 are in anti-parallel. In this case, the magnetic memory cell 100 does not conduct and the first and second magnetic layers remains isolated with each other, meaning the bit line stays at the first logic voltage, which when detected, may be a logic low. Therefore, the reading method provided by the second embodiment of the present invention identifies the direction of the second dipole 114 and outputs the corresponding logic bit (high or low) to the bit line.

Lastly, the above mentioned method may further include controlling the timing of the assertion of logic high/low bits to the bit line and the line select power line, so that the timing of the reading/writing may be controlled.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1-10. (canceled)

11. A method of reading a bit in the magnetic memory cell- wherein the magnetic memory cell comprises a first magnetic layer having a first dipole, a second magnetic layer having a second dipole, a conductive layer located between the first and second magnetic layers, a first word line positioned near the first magnetic layer to control the direction of the first dipole, and a second word line positioned near the second magnetic layer to control the direction of the second dipole, the method comprising the steps of:
(a) fixing the first dipole to a first direction;
(b) applying a first logic voltage to the first magnetic layer;
(c) applying the first logic voltage to the second magnetic layer;
(d) after the first logic voltage has been applied to the second magnetic layer, applying a second logic voltage to the second magnetic layer, wherein the second logic voltage is different from the first logic voltage; and
(e) detecting a voltage at the first magnetic layer, wherein when the first logic voltage is detected, the bit is read as a logic low, and when the second logic voltage is detected, the bit is read as a logic high.

12. The method of claim 11, wherein the direction of the first dipole is fixed by a control logic circuit.

13. The method of claim 11, wherein when the first logic voltage is detected, the first and second dipoles are anti-parallel.

14. The method of claim 11, wherein when the second logic voltage is detected, the first and the second magnetic layers are electrically connected.

15. The method of claim 11, wherein when the first logic voltage is detected, the first and second magnetic layers are electrically isolated.

16. The method of claim 11, further comprising controlling the timing of the applying of the first and second logic voltages to the first and second magnetic layers.

17. The method of claim 11, wherein the first and second logic voltages are applied to the first and second magnetic layers through a line select power line and a bit line, respectively.
